(19) United States
(12) Patent Application Publication
(10) Pub. No.: US 2017/0077911 A1
(43) Pub. Date: Mar. 16, 2017

(54) Method and Apparatus to Cancel an Offset Voltage

(71) Applicant: Knowles Electronics, LLC, Itasca, IL (US)

(72) Inventors: Dean A. Badillo, Schaumburg, IL (US); Michael Jennings, Plano, TX (US); Craig Stein, Naperville, IL (US)

(21) Appl. No.: 14/851,742

(22) Filed: Sep. 11, 2015

(51) Int. Cl. H03K 5/003; H03K 5/24

(52) U.S. Cl. CPC H03K 5/003; H03K 5/24

(57) ABSTRACT

These teachings provide for detecting an offset voltage corresponding to a circuit element having an input and an output. (The approaches taught herein will accommodate detecting that offset voltage at either the input and/or the output as desired.) Upon detecting the offset voltage a switch that connects the input of the circuit element to ground automatically closes to thereby ground the input. That switch remains open in the absence of detecting an offset voltage.

### TECHNICAL FIELD

These teachings relate generally to circuit elements and more particularly to responding to offset voltages that correspond to such circuit elements.

### BACKGROUND

Microphones are well known in the art and are typically used in conjunction with one or more amplifiers. Many known solutions in these regards are subject to operational frailties. For example, in some cases offset voltages can appear at the input of such an amplifier under some operating conditions (for example, when the microphone experiences a loud transient event) and those offset voltages can give rise to audible anomalies that are often highly distracting and/or annoying.

### BRIEF DESCRIPTION OF THE DRAWINGS

The above needs are at least partially met through provision of the method and apparatus to cancel an offset voltage described in the following detailed description, particularly when studied in conjunction with the drawings, wherein:

FIG. 1 comprises a schematic diagram as configured in accordance with the prior art;

FIG. 2 comprises a graph as configured in accordance with the prior art;

FIG. 3 comprises a graph as configured in accordance with the prior art;

FIG. 4 comprises a flow diagram as configured in accordance with various embodiments of these teachings;

FIG. 5 comprises a schematic diagram as configured in accordance with various embodiments of these teachings;

FIG. 6 comprises a schematic diagram as configured in accordance with various embodiments of these teachings;

FIG. 7 comprises a schematic diagram as configured in accordance with various embodiments of the invention; and

FIG. 8 comprises a schematic diagram as configured in accordance with various embodiments of these teachings.

Elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present teachings. Also, common but well-understood elements that are useful or necessary in a commercially feasible embodiment are often not depicted in order to facilitate a less obstructed view of these various embodiments of the present teachings. Certain actions and/or steps may be described or depicted in a particular order of occurrence while those skilled in the art will understand that such specificity with respect to sequence is not actually required. The terms and expressions used herein have the ordinary technical meaning as is accorded to such terms and expressions by persons skilled in the technical field as set forth above except where different specific meanings have otherwise been set forth herein.

### DETAILED DESCRIPTION

Generally speaking, these teachings provide for detecting an offset voltage corresponding to a circuit element having an input and an output. (The approaches taught herein will accommodate detecting that offset voltage at either the input and/or the output as desired.) Upon detecting the offset voltage a switch that connects the input of the circuit element to ground automatically closes to thereby ground the input. That switch remains open in the absence of detecting an offset voltage.

By one approach the foregoing circuit element comprises an amplifier that operably couples to a microphone. These teachings are particularly useful when applied in an application setting where the offset voltage comprises a naturally decaying offset voltage.

By one approach a comparator having one input coupled to the circuit element (for example, either the input or the output of the circuit element) and another input coupled to a reference voltage source serves to detect the offset voltage. If desired, the comparator so couples to the circuit element via a low-pass filter.

So configured, offset voltages can be quickly detected and responded to in a way that likely prevents those offset voltages from giving rise to inappropriate and/or annoying audible anomalies.

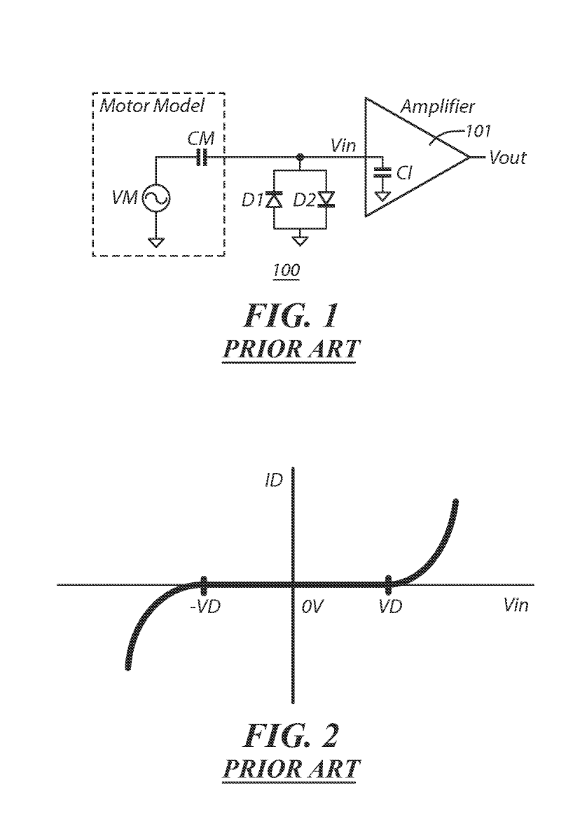

These and other benefits may become clearer upon making a thorough review and study of the following detailed description. Before describing these teachings in further detail, however, it may be helpful to first briefly recount certain characterizing aspects regarding a typical prior art application setting in these regards. FIG. 1 illustrates an example of a basic prior art microphone amplifier interface model 100.

Generally speaking, electronics that interface with capacitive sensors, such as a microphone, require a high input impedance in order to prevent undue signal loss. Accordingly, circuit elements such as amplifiers often use MOSFET or JFET input transistors because of the inherently high input impedance typically associated with such components. In such a case a bias voltage must be supplied to the input of the circuit for it to operate properly. That bias voltage must also be high impedance to prevent signal attenuation.

In FIG. 1 the capacitor denoted as CM represents the microphone motor capacitance. VM represents the voltage equivalent of the acoustic signal. CI represents the input capacitance of the amplifier 101, while Vin represents the input voltage to the amplifier 101 and Vout represents the output voltage of the amplifier 101. The amplifier 101 can have any gain but often has a unity gain.

When using miniature microphones, CM and CI are on the order of 1 pF and 100 fF respectively. In this example cross coupled diodes denoted by D1 and D2 connect across the input of the amplifier 101 and ground to provide a 0V bias point that provides a sufficiently high impedance to serve effectively in these regards.

Accordingly, the quiescent output voltage corresponding to this 0V input bias is VoutQ which typically differs from the input bias voltage. FIG. 2 depicts the voltage-current of the aforementioned cross coupled diodes. In a quiescent state these diodes have 0V across them, no current flows through them, and they present an effective impedance of greater than 10 trillion ohms which satisfies the aforementioned high impedance requirement. As the signal amplitude increases, the average diode impedance will also decrease. Generally speaking, this phenomenon will have a negligible effect until the signals approach plus or minus VD at which point the diodes begin to show significant conduction. For symmetric large signals, such as high amplitude sinusoids, the primary effect will be distortion as the diodes act to limit the signal swing at both positive and negative peaks.

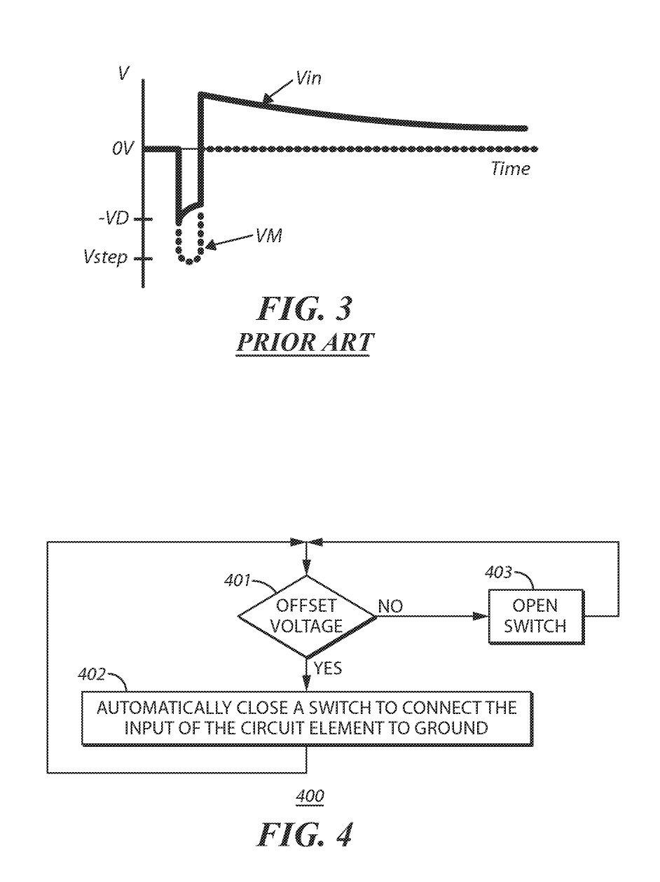

By way of an example, events such as a door shutting can result in an asymmetrical stimulus to the microphone. FIG. 3 presents a model of this effect presuming an ideal impulse. During the falling edge of VM, Vin attempts to follow according to the attenuation factor set by the capacitive divider formed by CM and CI. As Vin approaches −VD, the diodes will start to conduct and prevent further changes of Vin. Accordingly, Vin will be clamped to −VD as VM continues its negative transition.

While the VM impulse remains at its peak negative voltage, the conduction of the diodes begins to discharge Vin to 0V. VN attempts to follow VM again as it returns to zero. Now, however, a net charge remains on the input and VN slowly decays back to 0V. The decay can occur over several minutes because as VN returns to 0V, the diodes have less voltage across them, thereby causing their impedance to be increasingly higher. This offset substantially shifts the operating point of the amplifier 101 and typically degrades performance thereof.

FIG. 4 presents an illustrative process 400 that can help to at least ameliorate the undesired results described above that are attributable to the described offset voltage.

At block 401 this process 400 provides for detecting an offset voltage corresponding to a circuit element (such as the aforementioned amplifier 101) having an input and an output. In response to detecting that offset voltage, at block 402 this process 400 provides for automatically closing a switch that connects the input of the circuit element to ground. In all other cases this process 400 provides for opening that switch at block 403. Accordingly, this process 400 provides for opening that switch in response to detecting an absence of the offset voltage.

As noted above, while the circumstances giving rise to the offset voltage may yield a naturally decaying offset voltage, it may take a considerable amount of time for that offset voltage to naturally decay. As described above that decaying offset voltage can give rise to unwanted distortion during that potentially lengthy interval. In many application settings closing the aforementioned switch to connect the input of the circuit element to ground can result in almost immediately (for example, on the order of only a few milliseconds) dissipating the cause of the offset voltage such that almost immediately the offset voltage will be rendered undetectable and the switch can then again be opened.

These teachings are highly flexible in practice and will accommodate a variety of approaches and modifications to those approaches. A number of specific examples will now be presented for the sake of illustration. It shall be understood that no particular limitations are intended by way of the specifics of these examples.

### EXAMPLE 1

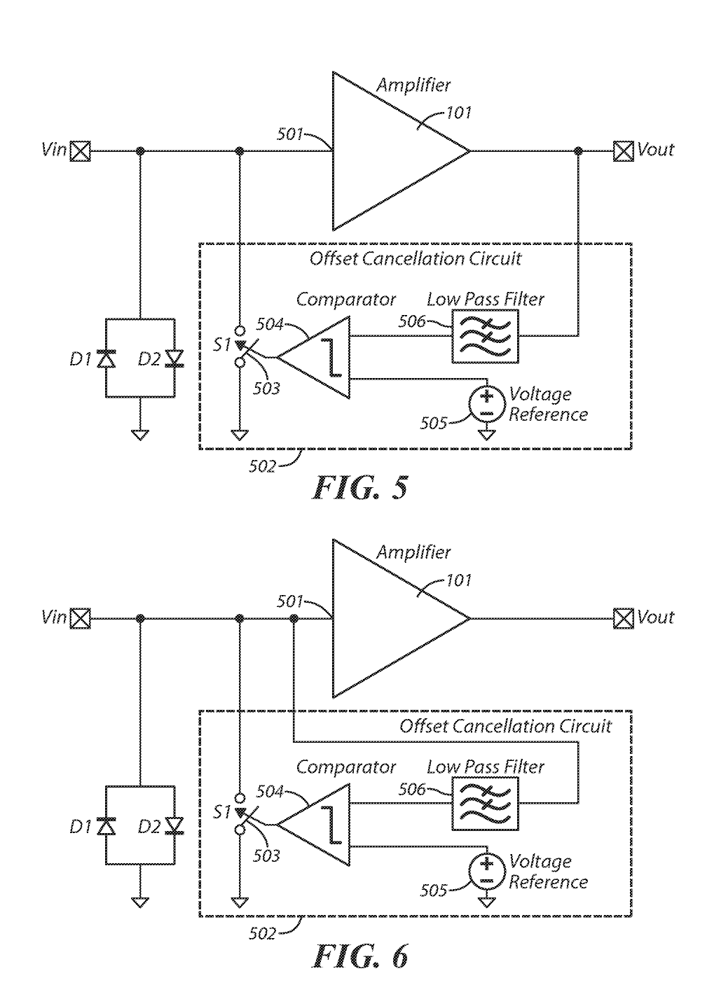

In the example presented in FIG. 5, an amplifier 101 operably couples at its input 501 to a microphone (not shown). As in the example provided above this input 501 also operably couples to a pair of grounded cross-coupled diodes denoted as D1 and D2. The amplifier 101 also connects to an offset cancellation circuit 502 that includes a grounded switch 503, a comparator 504 having its output coupled to control the aforementioned switch 503, a reference voltage source 505 that couples to one input of the comparator 504, and a low pass filter having its input connected to the output of the amplifier 100 and its output connected to the remaining input of the comparator 504. In this example the low pass filter 506 serves to attenuate alternating current (AC) signals while passing any direct current (DC) offsets. So configured, in this example the offset cancellation circuit 502 detects the offset voltage at the output of the amplifier 101.

So configured, the comparator 504 compares the quiescent output voltage of the amplifier 101 that corresponds with a reference voltage Vref that represents zero input offset voltage to the actual amplifier quiescent output voltage VoutQ. When VoutQ differs from Vref, the switch 503 closes to thereby short the amplifier input 501 to 0V and thereby remove the offset voltage.

As noted above, this response can serve to not only quickly remove the offset voltage from the amplifier 101 but can also serve to quickly dissipate the causative agent for that offset voltage. Accordingly, in many application settings the switch 503 will remain closed for only a very short period of time (such as from 2 to 10 ms).

### EXAMPLE 2

FIG. 6 provides a second illustrative example in these regards. In this example the offset cancellation circuit 502 responds to detection of the offset voltage at the input 501 of the amplifier 101 rather than the output thereof. In this case the voltage reference 505 is 0V. If an offset voltage is present on the input 501, that offset voltage passes through the low-pass filter 506 and again triggers the comparator 504 to close the switch 503 and thereby direct the offset voltage to ground.

### EXAMPLE 3

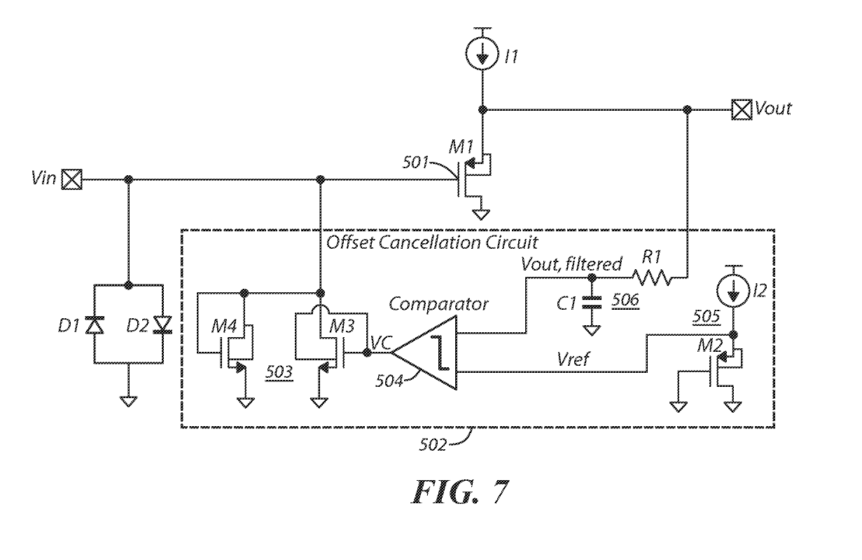

FIG. 7 provides a third illustrative example in these regards. In this example the offset cancellation circuit 502 is applied to a source follower with three external connections, Vsupply, ground, and Vout. The input is not external since it only connects to the motor. In this example the low-pass filter 506 comprises a resistor R1 and a capacitor C1.

The filtered output voltage from the low-pass filter 506 is compared by the comparator 504 to Vref. Vref is identical to VoutQ if the current source denoted as I2 equals the current source denoted as I1 and the MOSFET component denoted as M2 equals the MOSFET component denoted as M1. (It is also possible for Vref to match VoutQ by making current source I2 less than I1 and scaling MOSFET M2 appropriately.) An offset voltage at the input 501 will cause Vout(filtered) to differ from Vref and thereby switch the MOSFETs denoted as M3 and M4 (which comprise the aforementioned switch 503) to close and thereby short Vin to ground to remove the offset.

In some application settings the impedance versus voltage symmetry of the switch in an off-state around the quiescent input voltage can be important. If the impedance of the switch versus voltage is not the same for positive voltages as for negative voltages, the input waveform will be distorted such that the average voltage versus time is nonzero. In other words, if the switch impedance is not symmetrical, an offset can result from normal symmetric signals. The magnitude of this offset will depend on the input signal amplitude and the severity of the switch asymmetry. Signal dependent offsets could result in false triggering of the switch in the presence of high amplitude signals and thereby disrupt normal amplifier operation.

The switch 503 consisting of MOSFET M3 and MOSFET M4 offers symmetry in the off-state and low impedance in the on-state. In the off-state, the gate and well of MOSFET M3 is grounded through the comparator 504. In this condition, MOSFET M3 presents a high impedance for all positive input voltages and negative input voltages greater than the negative of the threshold voltage −Vtn.

If the input voltage drops to or below −Vtn, MOSFET M3 will conduct as the drain and source reverse function. Under this condition MOSFET M3 will limit the input signal to a minimum value, effectively clipping any large negative signals and resulting in a non-zero average signal. MOSFET M4 prevents this by mirroring MOSFET M3's limiting behavior for positive signals. If a positive input signal exceeds Vtn, MOSFET M4 will conduct and limit the signal to a maximum level.

The well of MOSFET M4 is connected to the input so that if MOSFET M3 and MOSFET M4 are matched, the electrical characteristics of the two transistors will also match. In the on-state, MOSFET M3 presents a low impedance by switching both the gate and the well. Raising the well voltage of MOSFET M3 utilizes the body effect to lower Vtn, which in turn lowers the impedance of MOSFET M3 below that which could be achieved by only switching the gate as is often conventionally done.

### EXAMPLE 4

Some microphone configurations feature two connections, an output connection and a ground connection. In this case, a current source is typically connected to the output and the voltage at the terminal of the current source is taken as the output. Again, the input connects to the motor and is not available external to the microphone.

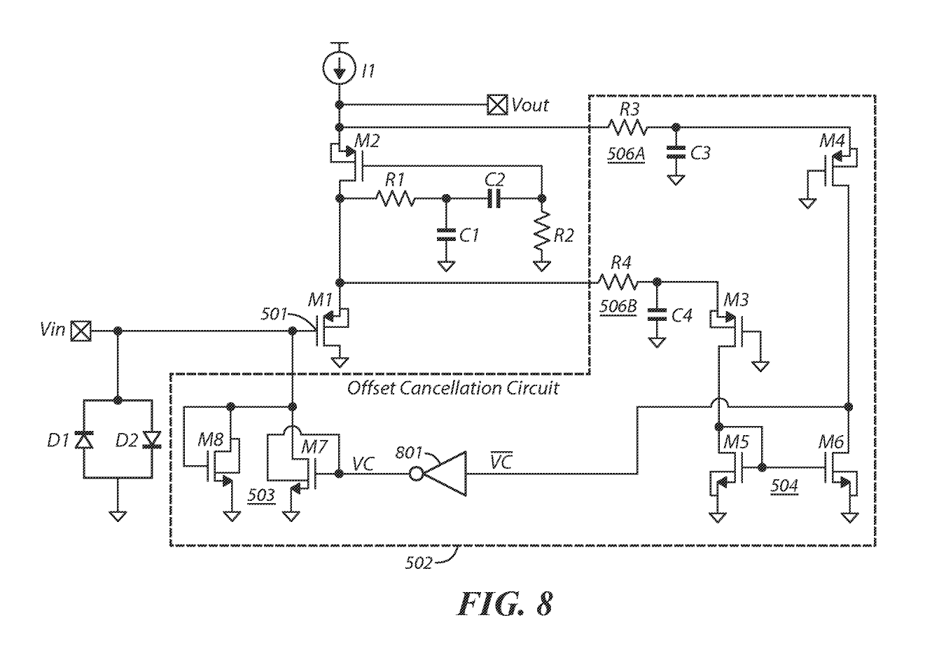

FIG. 8 provides a fourth illustrative example that applies the offset cancellation circuit concept 502 of these teachings to a two-wire microphone application setting. In this example the MOSFET denoted as M1 operates as a source follower. The signal at the source of MOSFET M1 is applied to a bandpass filter that includes the two resistors denoted as R1 and R2 and the two capacitors denoted as C1 and C2. The output of the bandpass filter is applied to the MOSFET denoted as M2.

When an offset voltage is present at the input, the source voltage of MOSFET M1 increases by approximately the same amount. Since the gate of MOSFET M2 is grounded, however, the source voltage of MOSFET M2 does not change in the presence of that offset voltage. Consequently, the source-drain voltage of MOSFET M2 decreases with an input offset voltage.

Accordingly, the source drain voltage of MOSFET M2, in the presence of an input offset voltage Vsd,off(M2), can be compared to the same voltage in the absence of an input offset Vsd(M2). When these differ, the offset cancellation circuit 502 triggers.

In this illustrative example any AC signals are removed by the offset cancellation circuit 502 by a first low-pass filter 506A (comprising a resistor denoted as R3 and a capacitor denoted as C3) and a second low-pass filter 506B (comprising a resistor denoted as R4 and a capacitor denoted as C4). In this example MOSFET M3 is proportional to MOSFET M1 and MOSFET M4 is proportional to MOSFET M2. In the absence of an offset, MOSFET M3 draws a nominal current Id(M3) and MOSFET M4 draws a nominal current Id(M4) where ID(M4)>ID(M3). ID(M3) is mirrored by MOSFET M5 and MOSFET M6. Because ID(M4)>ID(M3) and given channel length modulation, the voltage VC increases such that the drain voltage of MOSFET M4 approaches the source voltage and ID(M4)=ID(M6). Since the inverter's 801 supply voltage is the source of MOSFET M4 (that connection not being shown in this illustration), the inverter input is high and the output is low. The switch 503 consisting of MOSFET M7 and MOSFET M8 is off.

When a positive input offset voltage occurs, the source voltage of MOSFET M1 will increase along with the source voltage of MOSFET M3. Since the gate of MOSFET M3 is grounded, Vsd(M3) increases with positive offset voltages, thereby resulting in an increase in Id(M3). Now, ID(M4)<ID(M3) and VC approaches ground. In this way, MOSFET M5 and MOSFET M6 operate as a current mode comparator and switch the switch 503 on to thereby short the input 501 to ground.

With the voltage offset removed, ID (M3) returns to its nominal value and the switch 503 turns off. The duration of the switch-on time depends for the most part on time constants in the low-pass filters 506A and 506B.

Those skilled in the art will recognize that a wide variety of modifications, alterations, and combinations can be made with respect to the above described embodiments without departing from the scope of the invention, and that such modifications, alterations, and combinations are to be viewed as being within the ambit of the inventive concept.

1. A method comprising:
detecting a direct current (DC) offset voltage corresponding to a circuit element having an input and an output;
in response to detecting the DC offset voltage, automatically closing a switch to connect the input of the circuit element to ground;
in response to detecting an absence of the DC offset voltage, opening the switch.

2. The method of claim 1 wherein the circuit element comprises an amplifier.

3. The method of claim 1 wherein the input of the amplifier operably couples to a microphone.

4. The method of claim 3 wherein the input of the amplifier also operably couples to a pair of cross-coupled grounded diodes.

5. (canceled)

6. The method of claim 1 wherein detecting the DC offset voltage comprises using a comparator having an input that operably couples to the circuit element.

7. The method of claim 6 wherein detecting the DC offset voltage further comprises operably coupling another input to the comparator to a reference voltage source.

8. The method of claim 7 wherein the comparator operably couples to the circuit element via a low-pass filter.

9. The method of claim 1 wherein detecting the DC offset voltage corresponding to the circuit element comprises detecting the DC offset voltage at the output of the circuit element.

10. The method of claim 1 wherein detecting an offset voltage corresponding to a circuit element comprises detecting the offset voltage at the input of the circuit element.

11. An apparatus comprising:
a circuit element having an input and an output;
a switch that operably couples between the input of the circuit element and ground;
a direct current (DC) offset voltage cancellation circuit that operably couples to the circuit element and to the switch, the DC offset voltage cancellation circuit being configured to detect a DC offset voltage that corresponds to the circuit element and to responsively close the switch to thereby connect the input of the circuit element to ground whenever the DC offset voltage is detected.

12. The apparatus of claim 11 wherein the circuit element comprises an amplifier.

13. The apparatus of claim 11 wherein the input of the amplifier operably couples to a microphone.

14. The apparatus of claim 13 wherein the input of the amplifier also operably couples to a pair of cross-coupled grounded diodes.

15. The apparatus of claim 11 wherein the DC offset voltage cancellation circuit includes a comparator having an input that operably couples to the circuit element.

16. The apparatus of claim 15 wherein another input to the comparator operably couples to a reference voltage source.

17. The apparatus of claim 16 wherein the comparator operably couples to the circuit element via a low-pass filter.

18. The apparatus of claim 11 wherein the DC offset voltage cancellation circuit operably couples to the output of the circuit element.

19. The apparatus of claim 11 wherein the offset voltage cancellation circuit operably couples to the input of the circuit element.

20. The apparatus of claim 11 wherein the DC offset voltage cancellation circuit includes comparison means for comparing a signal corresponding to at least one of the input and the output of the circuit element with a reference voltage to thereby detect the DC offset voltage.
